(19) United States
(12) Patent Application Publication
(10) Pub. No.: US 2005/0000427 A1
(43) Pub. Date: Jan. 6, 2005

(54) Gas supplying apparatus for atomic layer deposition

(75) Inventors: Jae-cheol Lee, Gyeonggi-do (KR); Ran-ju Jung, Gyeonggi-do (KR); Youn-taek Ryu, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 10/823,625

(22) Filed: Apr. 14, 2004

(30) Foreign Application Priority Data
Jul. 2, 2003 (KR) 10-2003-0044542

(51) Int. Cl. C23C 16/00

(52) U.S. Cl. 118/715; 118/724; 118/726

(57) ABSTRACT

A gas supplying apparatus for atomic layer deposition, which generates a source gas by vaporizing a powder source and supplies the source gas into a reaction chamber of an atomic layer deposition apparatus, is provided. The apparatus includes a container containing the powder source, a cover, which is installed in an upper portion of the container and covers the container, a gas inlet tube, which supplies a carrier gas into the container and includes a preheating portion wound on an outer circumference of the container and a connection portion for connecting the preheating portion and a carrier gas storage tank, a gas outlet tube, which exhausts the source gas generated in the container together with the carrier gas, a heating unit heating the container and the preheating portion of the gas inlet tube together, a temperature sensor, which detects temperature in the container, and a temperature controller, which controls a power supply of the heating unit depending on a value of temperature detected by the temperature sensor.

This application claims the priority of Korean Patent Application No. 2003-44542, filed on Jul. 2, 2003, in the Korean Intellectual Property Office, the disclosure of which is incorporated herein in its entirety by reference.

### BACKGROUND OF THE INVENTION

1. Field of the Invention

The present invention relates to a gas supplying apparatus for atomic layer deposition, and more particularly, to a gas supplying apparatus for atomic layer deposition in which a solid powder source is vaporized, a source gas is generated, and the generated source gas is supplied into a reaction chamber of an atomic layer deposition apparatus.

2. Description of the Related Art

Typically, a process of depositing a thin film on a silicon wafer or glass substrate is required to manufacture a semiconductor device or a flat panel display. Recently, as the semiconductor device becomes highly integrated, a method of depositing a thin film having an excellent step coverage, a high aspect ratio, and a uniform thickness is needed. Atomic layer deposition (ALD) is used as a method of depositing a thin film. Atomic layer deposition (ALD) is a method in which gasses of about two kinds of source materials are sequentially supplied into a reaction chamber, an atomic layer is deposited on a substrate and is grown, thereby a forming a thin film to a desired thickness.

However, since most source materials are in a liquid state or a solid state at a room temperature, the source materials should be vaporized before they are supplied into the reaction chamber of an atomic layer deposition apparatus. Thus, a gas supplying unit for supplying a source gas into the reaction chamber is used in the atomic layer deposition apparatus. The gas supplying unit generates a source gas by vaporizing liquid precursor or by vaporizing a solid powder source, and then, supplies the source gas into the reaction chamber.

FIG. 1 shows a conventional gas supplying apparatus for atomic layer deposition. The conventional gas supplying apparatus shown in FIG. 1 generates a source gas by vaporizing a solid powder source and supplies the generated source gas together with a carrier gas into a reaction chamber of an atomic layer deposition apparatus. The gas supplying apparatus includes a container 10 in which a powder source is held and a cover 11, which is connected by a bolt 12 to an upper end of the container 10 and covers the container 10. The container 10 and the cover 11 are usually formed of stainless steel, so as to suppress corrosion.

A powder source supply hole 13 for supplying a powder source into the container 10, a gas inlet tube 14 through which a carrier gas is supplied into the container 10, and a gas outlet tube 17 through which the source gas in the container 10 is exhausted together with the carrier gas are installed in the cover 11. The gas inlet tube 14 is connected to a carrier gas storage tank 15, and the gas outlet tube 17 is connected to an ALD reaction chamber 40. Valves 16 and 18 for regulating gas flow are installed in each of the gas inlet tube 14 and the gas outlet tube 17. Meanwhile, a filter 19 for removing particles in the carrier gas and the source gas exhausted through the gas outlet tube 17 is installed in the gas outlet tube 17.

A first heater 21 for heating the container 10 is installed outside the container 10, to surround the container 10. A casing 20, which protects the container 10 and the first heater 21 and prevents heat generated in the first heater 21 from dissipating outside, is installed outside the first heater 21. A thermocouple 22 for measuring temperature in the container 10 is installed between the container 10 and the casing 20. A temperature value detected by the thermocouple 22 is transmitted to a temperature controller 23, and the temperature controller 23 controls a power supply 24 of the first heater 21 according to the detected temperature value so that the temperature in the container 10 is maintained at a constant level.

Meanwhile, since the carrier gas supplied into the container 10 should be heated to be equal to the temperature of the container 10, a second heater 26 is wound in the gas inlet tube 14. Thus, although not shown, a powder source for the second heater 26, a unit for measuring the temperature of the gas inlet tube 14, and a temperature controller are additionally installed in the conventional gas supplying apparatus.

Diaphragms 30 formed of a plurality of layers are installed in the container 10. Since the gas inlet tube 14 extends in the container 10 vertically, a powder source gas is dispersed by the carrier gas supplied into the container 10 through the gas inlet tube 14. Since the dispersed powder source is attached onto the surface of the diaphragms 30, the surface area of the powder source is increased, and the powder source can be more easily vaporized.

In the conventional gas supplying apparatus having the above structure, if current is applied to the first heater 21 from the power supply 24, the container 10 is heated, and the temperature in the container 10 increases. As such, since the temperature of the powder source in the container 10 increases, vaporization pressure is increased, and the powder source is easily vaporized, and thus, a source gas is generated. In this case, if the valves 16 and 18 respectively installed in the gas inlet tube 14 and the gas outlet tube 17 are opened, the carrier gas heated to a predetermined temperature by the second heater 26 is supplied into the container 10 through the gas inlet tube 14, and the source gas in the container 10 is exhausted through the gas outlet tube 17 together with the carrier gas. The carrier gas and the source gas exhausted from the container 10 through the gas outlet tube 17 flow in the ALD reaction chamber 40. As a result, a process of depositing an atomic layer thin film is performed in the ALD reaction chamber 40.

However, the conventional gas supplying apparatus includes the first heater 21 for heating the container 10 and the second heater 26 for heating the carrier gas separately. As such, the power supply for the first heater 21, thermocouple 22 and the temperature controller 23 for maintaining the temperature of the container 10 at a constant level, the power supply for the second heater 26, the temperature measuring unit and the temperature controller for maintaining the temperature of the carrier gas are needed. Like this, the conventional gas supplying apparatus has a complex structure. In addition, since the container 10 and the carrier gas respectively are heated by the separate heaters 21 and 26, a temperature difference therebetween occurs.

In the conventional gas supplying apparatus, the diaphragms 30 are installed in the container 10, and the powder source is dispersed, such that a vaporization efficiency of the powder source is increased. However, since the dispersed powder gas is easily exhausted together with the carrier gas through the gas outlet tube 17, the powder gas may flow to the ALD reaction chamber 40. Thus, in the conventional gas supplying apparatus, as described above, the filter 19 is installed in the gas outlet tube 17 such that the powder source is prevented from flowing to the ALD reaction chamber 40. However, it is very difficult to completely filter a fine powder source even though installing the filter 19, and gas flow, that is, the supplying amount of the source gas is reduced due to the filter 19.

In addition, in the conventional gas supplying apparatus, the container 10 is formed of stainless steel, so as to suppress corrosion. However, after long-term use, as shown in FIG. 2, due to the reaction between the powder source and the container 10, the container 10 may be corroded, or the powder source may be deteriorated.

### SUMMARY OF THE INVENTION

The present invention provides a gas supplying apparatus for atomic layer deposition having an improved structure in which a container containing a powder source and a carrier gas supplied into the container are heated together by one heating unit.

The present invention also provides a gas supplying apparatus for atomic layer deposition having an improved structure in which dispersion of a powder source is suppressed and the powder source is prevented from exhausting through a gas outlet tube.

The present invention also provides a gas supplying apparatus for atomic layer deposition having an improved structure in which corrosion of a container and deterioration of a powder source are prevented.

According to an aspect of the present invention, there is provided a gas supplying apparatus for atomic layer deposition, which generates a source gas by vaporizing a powder source and supplies the source gas into a reaction chamber of an atomic layer deposition apparatus, the apparatus comprising a container containing the powder source; a cover, which is installed in an upper portion of the container and covers the container; a gas inlet tube, which supplies a carrier gas into the container and includes a preheating portion wound on an outer circumference of the container and a connection portion for connecting the preheating portion and a carrier gas storage tank; a gas outlet tube, which exhausts the source gas generated in the container together with the carrier gas; a heating unit heating the container and the preheating portion of the gas inlet tube together; a temperature sensor, which detects temperature in the container; and a temperature controller, which controls a power supply of the heating unit depending on a value of temperature detected by the temperature sensor.

The heating unit may be a heater, which is installed to surround the container and the preheating portion of the gas inlet tube. In this case, the apparatus may further comprise a casing, which surrounds the heater and the container for protection. In addition, the casing may be formed of an adiabatic material, so as to prevent heat generated in the heater from dissipating outside, or an adiabatic material may be attached inside the casing such that heat generated in the heater is prevented from dissipating outside.

The heating unit may be a heater, which is supported by the cover, is placed in the container, and heats the container. In this case, the apparatus further comprises a casing, which surrounds the heater and the container for protection. In addition, the casing may be formed of an adiabatic material, so as to prevent heat generated in the heater from dissipating outside, or an adiabatic material may be attached inside the casing such that heat generated in the heater is prevented from dissipating outside.

The apparatus may further comprise a casing, which surrounds the container and the preheating portion of the gas inlet tube, and the heating unit comprises a working fluid, which is filled in a space between the container and the casing; and a thermoelectric device, which is installed to contact an outside of the casing thermally and heats the working fluid.

In this case, the thermoelectric device may be a Peltier device, which installed to contact a bottom surface of the casing thermally. A thermal conductive material may be interposed between the casing and the thermoelectric device. The thermal conductive material may be a thermal compound or a thermal pad.

The preheating portion of the gas inlet tube may be wound several times along an outer circumference of the container, or the preheating portion of the gas inlet tube may be wound in a serpentine pattern along an outer circumference of the container.

The container may be formed of quartz.

The container may include an internal container holding the powder source and an external container surrounding the internal container. In this case, the internal container may be formed of quartz, and the external container may be formed of a metallic material. The external container may be formed of stainless steel.

A plurality of guide plates formed of a plurality of layers may be formed in the container, so as to elongate a gas exhaust path. The plurality of guide plates may be installed to form a gas exhaust path having a zigzag shape.

A plurality of steps may be formed at a predetermined gap in the container in a height direction, and the plurality of guide plates respectively may be supported by the plurality of steps, and the plurality of guide plates may be formed of glass or quartz.

An outlet end of the gas inlet tube may be installed such that the carrier gas is not injected toward the powder source. In this case, the outlet end of the gas inlet tube may be horizontally installed in a middle portion of the container.

The gas outlet tube may be horizontally installed near an upper end of the container.

The temperature sensor may be a thermocouple. Valves for regulating gas flow may be installed in each of the connection portions of the gas inlet tube and the gas outlet tube. A powder source supply hole for supplying a powder source into the container may be installed in the cover.

### BRIEF DESCRIPTION OF THE DRAWINGS

The above aspects and advantages of the present invention will become more apparent by describing in detail exemplary embodiments thereof with reference to the attached drawings in which:

FIG. 1 is a vertical cross-sectional view schematically showing a conventional gas supplying apparatus for atomic layer deposition;

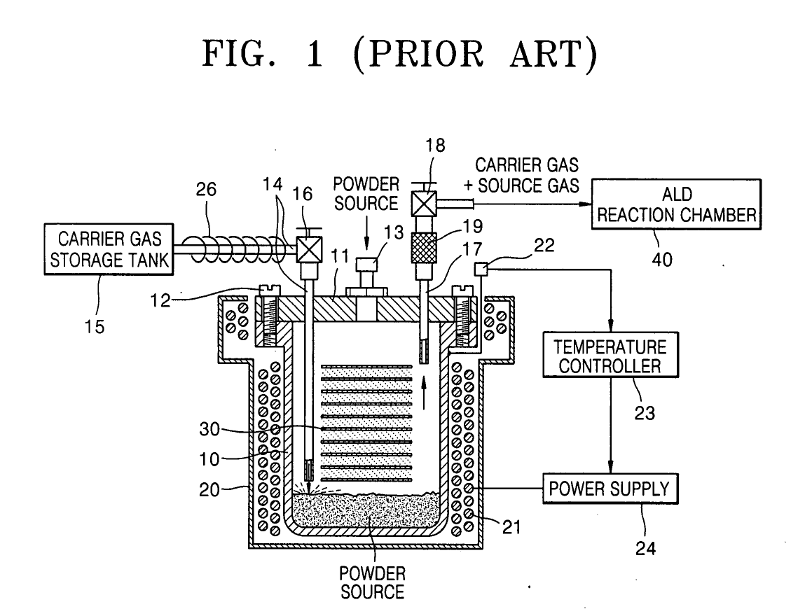

FIG. 2 is a photo showing a state where an inside of a container of the conventional gas supplying apparatus is corroded;

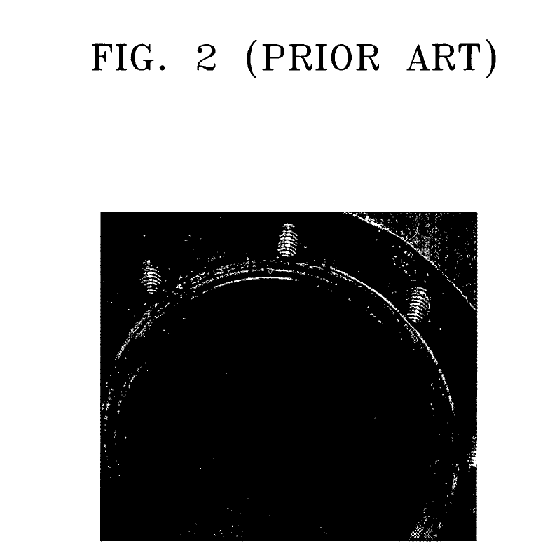

FIG. 3 is a vertical cross-sectional view showing a gas supplying apparatus for atomic layer deposition according to a first embodiment of the present invention;

FIGS. 4A and 4B are partial cutting perspective views showing two shapes of a gas inlet tube installed outside the container shown in FIG. 3;

FIG. 5 is a vertical cross-sectional view showing a gas supplying apparatus for atomic layer deposition according to a second embodiment of the present invention;

FIG. 6 is a vertical cross-sectional view showing a gas supplying apparatus for atomic layer deposition according to a third embodiment of the present invention; and

FIG. 7 is a vertical cross-sectional view showing a gas supplying apparatus for atomic layer deposition according to a fourth embodiment of the present invention.

### DETAILED DESCRIPTION OF THE INVENTION

Hereinafter, the present invention will be described in detail by describing a preferred embodiment of the present invention with reference to the accompanying drawings. This invention may, however, be embodied in many different forms and should not be construed as being limited to the embodiments set forth herein. Same reference numerals denote elements having same functions, and the size and thickness of an element may be exaggerated for clarity.

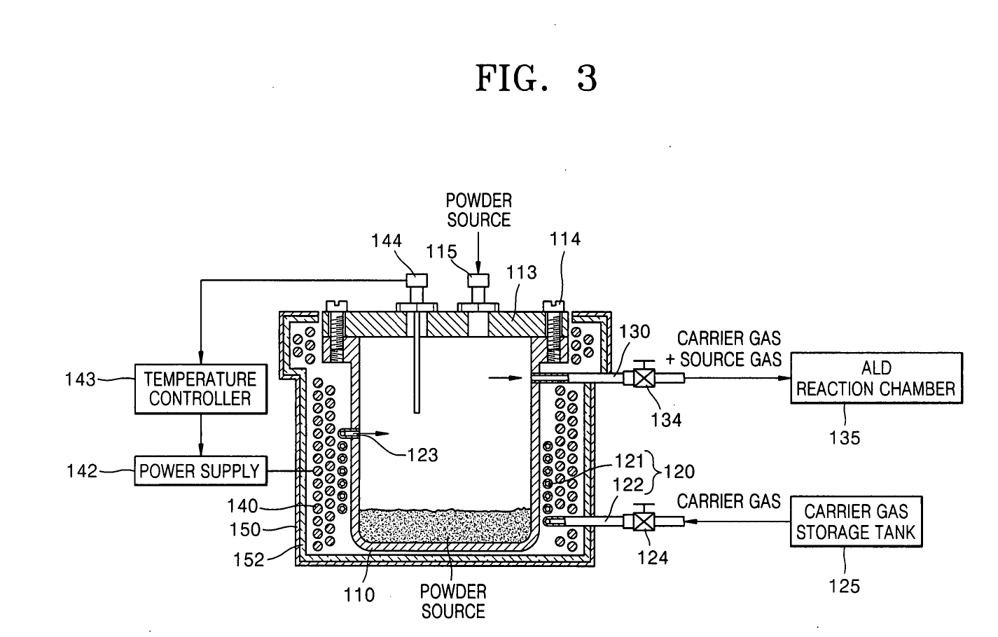

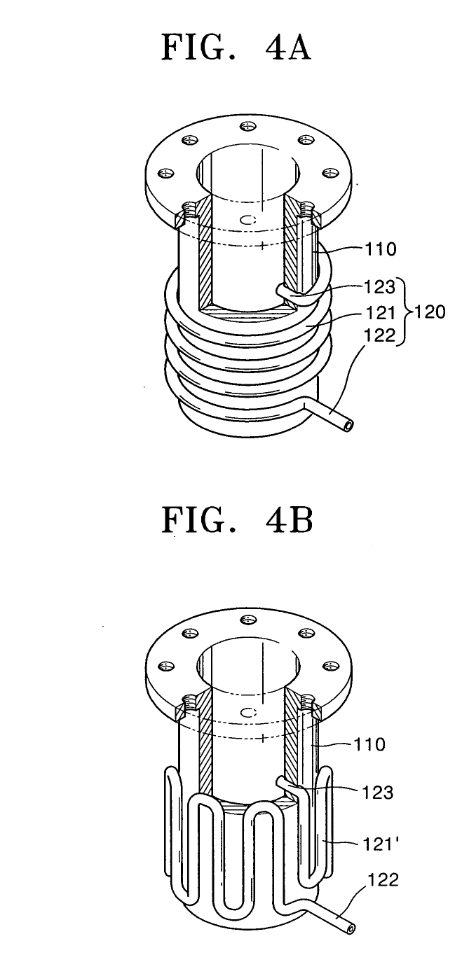

FIG. 3 is a vertical cross-sectional view showing a gas supplying apparatus for atomic layer deposition according to a first embodiment of the present invention, and FIGS. 4A and 4B are partial cutting perspective views showing two shapes of a gas inlet tube installed outside the container shown in FIG. 3.

Referring to FIG. 3, the gas supplying apparatus for atomic layer deposition according to the first embodiment of the present invention includes a container 110 containing a powder source and a cover 113, which is installed in an upper portion of the container 110 and covers the container 110. The cover 113 is connected by a bolt 114 to an upper end of the container 110. The powder source contained in the container 110 is formed by forming a source material for thin film deposition, such as HfCl₄, in a fine powder state.

The container 110 and the cover 113 may be formed of stainless steel, so as to suppress corrosion. However, more preferably, the container 110 is formed of quartz. If the container 110 is formed of quartz, a chemical reaction between the powder source contained in the container 110 and the container 110 does hardly occur. Thus, even after long-term use, corrosion of the container 110 and deterioration of the powder source can be prevented.

A gas inlet tube 120 through which a carrier gas is supplied into the container 110 and a gas outlet tube 130 through which a source gas generated in the container 110 is exhausted together with the carrier gas are installed in the container 110. An inert gas, such as an Argon gas or a nitrogen gas may be used as the carrier gas.

The gas inlet tube 120 includes a preheating portion 121 wound on an outer circumference of the container 110 and a connection portion 122, which connects the preheating portion 121 to a carrier gas storage tank 125. The preheating portion 121 of the gas inlet tube 120 is wound on the outer circumference of the container 110 in various shapes in which it has a sufficiently large length. For example, as shown in FIG. 4A, the preheating portion 121 of the gas inlet tube 120 may have a coil shape in which it is wound several times along the outer circumference of the container 110. In addition, as shown in FIG. 4B, a preheating portion 121′ may be wound in a serpentine pattern along the outer circumference of the container 110. Since the preheating portions 121 and 121′ having this shape have considerably large lengths, the carrier gas supplied into the container 110 through the preheating portions 121 and 121′ is sufficiently preheated by the heater 140 that will be described later such that the temperature of the carrier gas is increased to a desired temperature, that is, equal to the temperature of the container 110.

An outlet end 123 of the gas inlet tube 120 is installed such that the carrier gas is not injected toward the powder source contained in the container 110. Preferably, the outlet end 123 of the gas inlet tube 120 is horizontally installed in a middle portion of the container 110. The carrier gas is horizontally injected from the outlet end 123 of the gas inlet tube 120. Thus, the powder source contained in the container 110 is hardly dispersed. Thus, the dispersed powder source is exhausted together with the carrier gas through the gas outlet tube 130 such that a prior-art problem that the powder gas flows to the ALD reaction chamber 135 is solved. As such, a prior-art filter does not need to be installed in the gas outlet tube 130. Thus, a prior-art problem that gas flow, that is, the supplying amount of a source gas is reduced due to the filter does not occur.

Meanwhile, a valve 124 for regulating the flow of the carrier gas is installed in the connection portion 122 of the gas inlet tube 120.

The gas outlet tube 130 is connected between the container 110 and the ALD reaction chamber 135. The source gas generated in the container 110 through the gas outlet tube 130 is exhausted from the container 110 together with the carrier gas and is supplied into the ALD reaction chamber 135. As shown in FIG. 3, the gas outlet tube 130 may be horizontally installed near the upper end of the container 110. Meanwhile, the gas outlet tube 130 may be vertically installed in the cover 113. A valve 134 for regulating the flow of the carrier gas and the source gas is installed in the gas outlet tube 130.

The gas supplying apparatus according to the present invention includes a heater 140, which is installed to surround the container 110 and the preheating portion 121 of the gas inlet tube 120. Thus, the heater 140 heats the container 110 and the preheating portion 121 of the gas inlet tube 120 together. In particular, as described previously, the preheating portion 121 of the gas inlet tube 120 has a very large length. Thus, the carrier gas flowing through the preheating portion 121 may be sufficiently preheated by the heater 140 to a desired temperature.

As described above, according to the present invention, the container 110 containing the powder source and the carrier gas flowing through the preheating portion 121 are heated by one heater 140 together. Thus, the carrier gas is easily heated to the same temperature as the temperature of the container 110.

The container 110 is heated by the heater 140 such that temperature in the container 110 increases. As such, the temperature of the powder source in the container 110 increases. Thus, a vaporization pressure of the powder source increases, and the powder source is easily vaporized, and a source gas is generated. In this case, if the valves 124 and 134 installed in the gas inlet tube 120 and the gas outlet tube 130 are opened, the carrier gas flows to the container 110 through the gas inlet tube 120, and the source gas in the container 110 is exhausted through the gas outlet tube 130 together with the carrier gas. In this case, the carrier gas flowing into the container 110 through the gas inlet tube 120 is preheated by the heater 140 to the same temperature as the temperature in the container 110. Thus, even though the carrier gas flows into the container 110, the temperature in the container 110 is not changed. Thus, vaporization of the powder source may be stably performed. The carrier gas and the source gas exhausted from the container 110 through the gas outlet tube 130 are supplied into the ALD reaction chamber 135. As such, a process of depositing an atomic layer thin film is performed in the ALD reaction chamber 135.

The thermocouple 144 is installed in the cover 113 as a temperature sensor for measuring the temperature in the container 110. Another device may be used as the temperature sensor. A power supply 142 for supplying current to the heater 140 is connected to the heater 140, and the power supply 142 is controlled by a temperature controller 143. The temperature controller 143 controls the power supply 143 depending on a value of temperature detected by the thermocouple 144, such that the temperature in the container 110 is maintained to a predetermined temperature at a constant level. Specifically, the temperature controller 143 compares the value of temperature detected by the thermocouple 144 with a predetermined reference temperature. If the detected temperature value is higher than the reference temperature, the temperature controller 143 cuts off the current supplied to the heater 140. Conversely, if the detected temperature value is lower than the reference temperature, current is supplied to the heater 140 such that the temperature in the container 110 increases.

In this way, only one heater 140 is provided to the gas supplying apparatus according to the present invention, and the power supply 142 for the heater 140, the thermocouple 144, and the temperature controller 143 are provided by ones to the gas supplying apparatus according to the present invention. Thus, the structure of the gas supplying apparatus according to the present invention is simplified compared to a prior-art gas supplying apparatus.

The gas supplying apparatus according to the present invention may further include a casing 150 surrounding the heater 140 and the container 110. Thus, the heater 140 and the container 110 may be protected by the casing 150 from external shock. The casing 150 may be formed of an adiabatic material. In this case, heat generated in the heater 140 is prevented from dissipating outside such that an energy efficiency increases. Meanwhile, an adiabatic material 152 may be attached inside the casing 150 such that heat generated in the heater 140 is prevented from dissipating outside.

Meanwhile, preferably, a powder source supply hole 115 for supplying a powder source into the container 110 is provided to the cover 113. The cover 113 is opened, and the powder source may be supplied into the container 110. However, as described above, by providing the powder source supply hole 115 to the cover 113, supplement of the powder source can be easily performed.

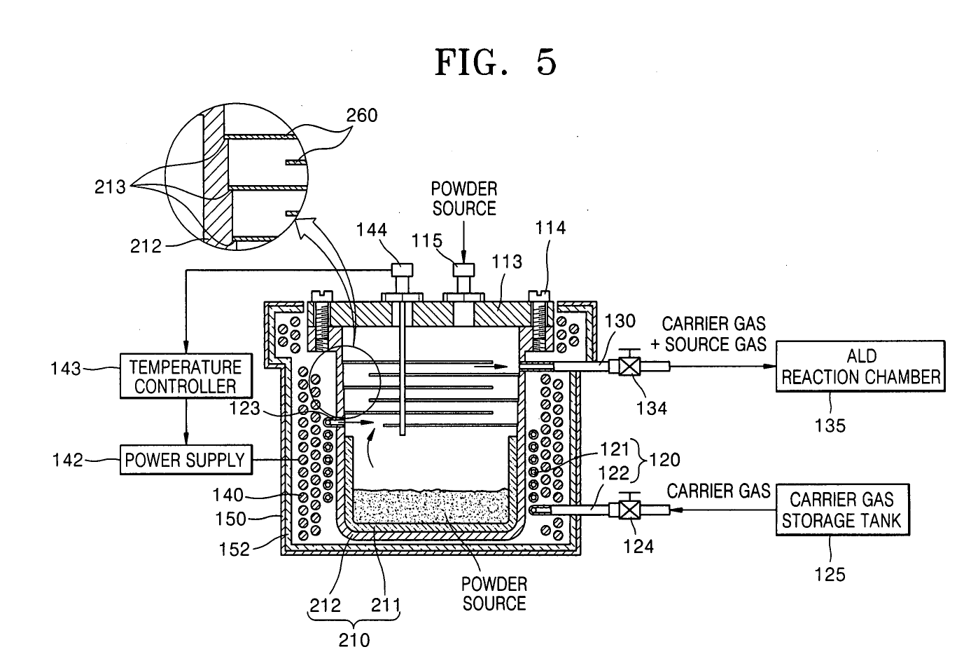

FIG. 5 is a vertical cross-sectional view showing a gas supplying apparatus for atomic layer deposition according to a second embodiment of the present invention. The gas supplying apparatus shown in FIG. 5 is the same as the gas supplying apparatus shown in FIG. 3 except for the structure of a container and except that a plurality of guide plates are installed in the container. Thus, hereinafter, detailed descriptions of the same elements as the elements of the gas supplying apparatus shown in FIG. 3 will be omitted.

Referring to FIG. 5, a container 210 of the gas supplying apparatus for atomic layer deposition according to the second embodiment of the present invention includes an internal container 211 containing a powder source and an external container 212 surrounding the internal container 211. Preferably, the internal container 211 is formed of quartz, and the external container 212 is formed of a metallic material, for example, stainless steel.

In this way, if the internal container 211 containing the powder source is formed of quartz, as described previously, even after long-term use, corrosion of the container 210 and deterioration of the powder source are prevented, and the external container 212 is formed of stainless steel such that the whole strength of the container 210 increases.

A plurality of guide plates 260 formed of a plurality of layers may be installed in the container 210, so as to elongate a gas exhaust path. In particular, preferably, the plurality of guide plates 260 are installed to form a gas exhaust path having a zigzag shape, as shown in FIG. 5. In this way, if the plurality of guide plates 260 are installed in the container 210, the gas exhaust path is elongated such that the powder source is more effectively prevented from being exhausted together with a carrier gas.

In order to install the plurality of guide plates 260 in the container 210, a plurality of steps 213 are formed at a predetermined gap in the external container 212 in a height direction. An edge of each plurality of guide plates 260 is supported by the plurality of steps 213. The plurality of guide plates 260 may be formed of stainless steel. However, as described previously, preferably, the plurality of guide plates 260 are formed of quartz or glass, so as to obtain long-term corrosion resistance and prevent deterioration of the powder source.

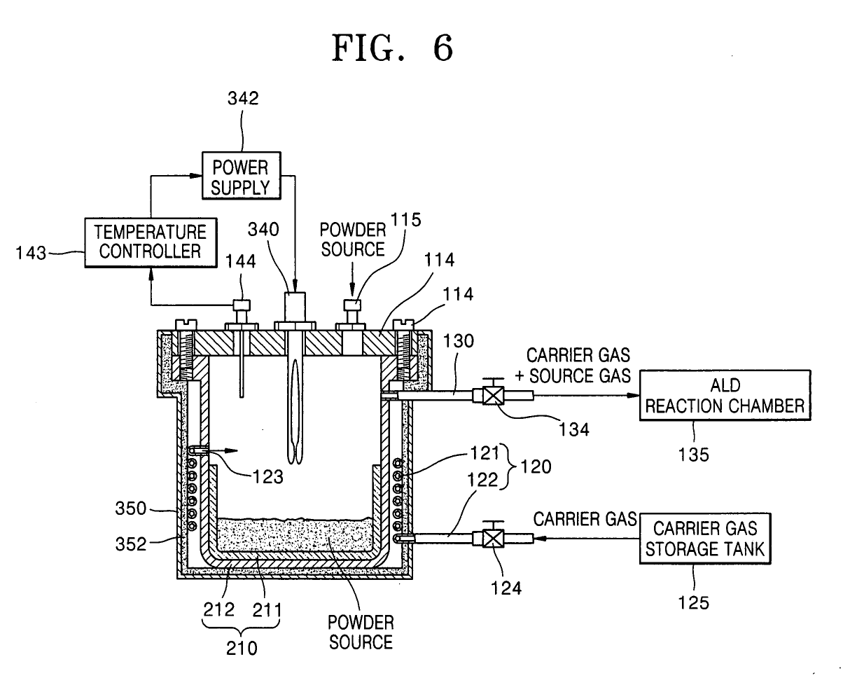

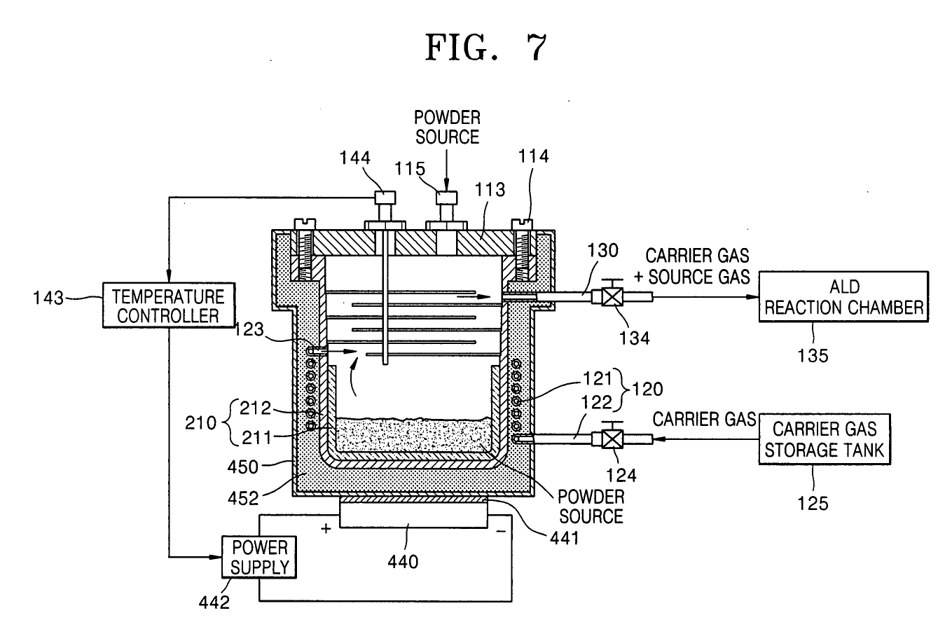

Meanwhile, the plurality of guide plates 260 may also be employed both in the gas supplying apparatus shown in FIG. 3 and the gas supplying apparatus shown in FIGS. 6 and 7 that will be described later.

FIG. 6 is a vertical cross-sectional view showing a gas supplying apparatus for atomic layer deposition according to a third embodiment of the present invention. The gas supplying apparatus shown in FIG. 6 is the same as the gas supplying apparatus shown in FIG. 5 except for the structure and installation position of a heater. Thus, hereinafter, only a characterizing portion of the present embodiment will be described.

Referring to FIG. 6, the gas supplying apparatus for atomic layer deposition according to the third embodiment of the present invention includes a heater 340 installed at the cover 113 of the container 210. The heater 340 is supported by the cover 113, is placed in the container 210, and heats the container 210. As such, the container 210 is heated, and the preheating portion 121 of the gas inlet tube 120 wound on the outer circumference of the container 210 may be heated due to heat conduction.

Even in the present embodiment, the casing 350 which surrounds the container 210 and the preheating portion 121 of the gas inlet tube 120 to protect them, may be provided. The casing 350 may be formed of an adiabatic material. In this case, heat generated in the heater 340 is prevented from dissipating outside such that an energy efficiency increases. Meanwhile, the adiabatic material 352 may be attached inside the casing 350 such that heat generated in the heater 340 is prevented from dissipating outside.

Like in the above-described embodiments, the gas supplying apparatus for atomic layer deposition according to the third embodiment of the present invention includes a thermocouple 144 for measuring temperature in the container 210 and a temperature controller 143 for controlling a power supply 342 of the heater 340 depending on a value of temperature detected by the thermocouple 144.

As shown in FIG. 6, the container 210 may include an internal container 211 and an external container 212. However, the container 210 may include one container, as shown in FIG. 3. The plurality of guide plates 260 shown in FIG. 5 may be installed in the container 210.

FIG. 7 is a vertical cross-sectional view showing a gas supplying apparatus for atomic layer deposition according to a fourth embodiment of the present invention. The gas supplying apparatus shown in FIG. 7 is the same as the gas supplying apparatus shown in FIG. 5 except that a thermoelectric device is used as a heating unit. Thus, hereinafter, only a characterizing portion of the present embodiment will be described.

Referring to FIG. 7, the gas supplying apparatus for atomic layer deposition according to the fourth embodiment of the present invention uses a thermoelectric device 440 as a unit for heating the container 210 and the preheating portion 121 of the gas inlet tube 120 together.

Specifically, a casing 450 which surrounds the container 210 and the preheating portion 121 of the gas inlet tube 120, is installed outside the container 210. A working fluid 452 is filled in a space between the casing 450 and the container 210. Water may be used as the working fluid 452. However, if a heating temperature is more than 100° C., a material having a higher evaporation point may be used as the working fluid 452.

The thermoelectric device 440 is installed to contact an outside of the casing 450 thermally. The thermoelectric device 440 may be installed in any position of the outside of the casing 450. However, preferably, the thermoelectric device 440 is installed on a bottom surface of the casing 450.

In order to improve a heat transfer efficiency between the casing 450 and the thermoelectric device 440, preferably, a material having excellent thermal conductivity is interposed between the casing 450 and the thermoelectric device 440. A thermal pad 441 is typically used as the thermal conductive material, or a thermal compound may be used as the thermal conductive material. Thus, thermal contact between the casing 450 and the thermoelectric device 440 may be more reliably performed.

When two types of different metals are bonded to each other and current flows, the generation or absorption of heat in proportion to the current occurs in a junction. The generation and absorption of heat occurs reversibly depending on the direction of current regardless of an ambient temperature. If the direction of current is reversed, the generation and absorption of heat becomes reverse. A device using this phenomenon is the thermoelectric device 440. Various types of devices may be used as the thermoelectric device 440. However, preferably, a Peltier device is used as the thermoelectric device 440.

As described above, in the present embodiment, the container 210 and the preheating portion 121 of the gas inlet tube 120 are heated together using the thermoelectric device 440. Specifically, if a predetermined direction of current flows through the thermoelectric device 440, heat is generated in the thermoelectric device 440. Generated heat is transferred to the working fluid 452 through the thermal pad 441 and the casing 450 such that temperature of the working fluid 452 increases. The container 450 and the preheating portion 121 of the gas inlet tube 120 may be uniformly heated due to convection of the working fluid 452 between the container 210 and the casing 450.

The thermocouple 144 for measuring temperate in the container 210 is installed in the cover 113 of the container 210. A power supply 442 for supplying current is connected to the thermoelectric device 440, and the power supply 442 is controlled by the temperature controller 143. Specifically, the temperature controller 143 compares the temperature value detected by the thermocouple 144 with a predetermined reference temperature. If the detected temperature value is higher than the reference temperature, current supplied to the thermoelectric device 440 from the power supply 442 is cut off. Conversely, if the detected temperature value is lower than the reference temperature, the temperature controller 143 supplies current to the thermoelectric device 440 from the power supply 442. In this case, current flows in a direction in which heat is generated in the thermoelectric device 440. As described above, by controlling the power supply 442, the temperature in the container 210 can be maintained at a constant level.

As described above, the gas supplying apparatus for atomic layer deposition according to the present invention has the following advantages. First, since a container containing a powder source and a carrier gas can be heated together using one heating unit, temperature of the container and temperature of the carrier gas can be maintained at the same level, and a structure of the gas supplying apparatus is simplified. Second, since the carrier gas is horizontally supplied into the container through a gas inlet tube and dispersion of the powder source does hardly occur, the powder source is prevented from flowing to an ALD reaction chamber through a gas outlet tube. In particular, when a guide plate for elongating a gas exhaust path is installed in the container, the powder source is more effectively prevented from being exhausted together with the carrier gas. Thus, since a filter does not need to be installed in the gas outlet tube, gas flow, that is, the supplying amount of a source gas is not reduced due to a filter. Third, a powder source container is formed of quartz such that even after long-term use, corrosion of the container and deterioration of the powder source can be prevented.

While this invention has been particularly shown and described with reference to preferred embodiments thereof, it will be understood by those skilled in the art that various changes in form and details may be made therein without departing from the spirit and scope of the invention as defined by the appended claims.

1. A gas supplying apparatus for atomic layer deposition, which generates a source gas by vaporizing a powder source and supplies the source gas into a reaction chamber of an atomic layer deposition apparatus, the apparatus comprising:
a container containing the powder source;
a cover, which is installed in an upper portion of the container and covers the container;
a gas inlet tube, which supplies a carrier gas into the container and includes a preheating portion wound on an outer circumference of the container and a connection portion for connecting the preheating portion and a carrier gas storage tank;
a gas outlet tube, which exhausts the source gas generated in the container together with the carrier gas;
a heating unit, heating the container and the preheating portion of the gas inlet tube together;
a temperature sensor, which detects temperature in the container; and
a temperature controller, which controls a power supply of the heating unit depending on a value of temperature detected by the temperature sensor.

2. The apparatus of claim 1, wherein the heating unit is a heater, which is installed to surround the container and the preheating portion of the gas inlet tube.

3. The apparatus of claim 2, further comprising a casing, which surrounds the heater and the container for protection.

4. The apparatus of claim 3, wherein the casing is formed of an adiabatic material, so as to prevent heat generated in the heater from dissipating outside.

5. The apparatus of claim 3, wherein an adiabatic material is attached inside the casing such that heat generated in the heater is prevented from dissipating outside.

6. The apparatus of claim 1, wherein the heating unit is a heater, which is supported by the cover, is placed in the container, and heats the container.

7. The apparatus of claim 6, further comprising a casing, which surrounds the heater and the container for protection.

8. The apparatus of claim 6, wherein the casing is formed of an adiabatic material, so as to prevent heat generated in the heater from dissipating outside

9. The apparatus of claim 6, wherein an adiabatic material is attached inside the casing such that heat generated in the heater is prevented from dissipating outside.

10. The apparatus of claim 1, further comprising a casing, which surrounds the container and the preheating portion of the gas inlet tube,
wherein the heating unit comprises:
a working fluid, which is filled in a space between the container and the casing; and
a thermoelectric device, which is installed to contact an outside of the casing thermally and heats the working fluid.

11. The apparatus of claim 10, wherein the thermoelectric device is installed to contact a bottom surface of the casing thermally.

12. The apparatus of claim 10, wherein the thermoelectric device is a Peltier device.

13. The apparatus of claim 10, wherein a thermal conductive material is interposed between the casing and the thermoelectric device.

14. The apparatus of claim 13, wherein the thermal conductive material is a thermal compound or a thermal pad.

15. The apparatus of claim 1, wherein the preheating portion of the gas inlet tube is wound several times along an outer circumference of the container.

16. The apparatus of claim 1, wherein the preheating portion of the gas inlet tube is wound in a serpentine pattern along an outer circumference of the container.

17. The apparatus of claim 1, wherein the container is formed of quartz.

18. The apparatus of claim 1, wherein the container includes an internal container holding the powder source and an external container surrounding the internal container.

19. The apparatus of claim 18, wherein the internal container is formed of quartz, and the external container is formed of a metallic material.

20. The apparatus of claim 19, wherein the external container is formed of stainless steel.

21. The apparatus of claim 1, wherein a plurality of guide plates formed of a plurality of layers are formed in the container, so as to elongate a gas exhaust path.

22. The apparatus of claim 21, wherein the plurality of guide plates are installed to form a gas exhaust path having a zigzag shape.

23. The apparatus of claim 21, wherein a plurality of steps are formed at a predetermined gap in the container in a height direction, and the plurality of guide plates respectively are supported by the plurality of steps.

24. The apparatus of claim 21, wherein the plurality of guide plates are formed of glass or quartz.

25. The apparatus of claim 1, wherein an outlet end of the gas inlet tube is installed such that the carrier gas is not injected toward the powder source.

26. The apparatus of claim 25, wherein the outlet end of the gas inlet tube is horizontally installed in a middle portion of the container.

27. The apparatus of claim 1, wherein the gas outlet tube is horizontally installed near an upper end of the container.

28. The apparatus of claim 1, wherein the temperature sensor is a thermocouple.

29. The apparatus of claim 1, wherein valves for regulating gas flow are installed in each of the connection portions of the gas inlet tube and the gas outlet tube.

30. The apparatus of claim 1, wherein a powder source supply hole for supplying a powder source into the container is installed in the cover.
